(19) United States
(12) Patent Application Publication
(10) Pub. No.: US 2016/0378175 A1
(43) Pub. Date: Dec. 29, 2016

(54) POWER SUPPLY CIRCUIT FOR A COMPUTING SERVER

(71) Applicant: Lenovo Enterprise Solutions (Singapore) Pte. Ltd., Singapore (SG)

(72) Inventors: Chih-Wei Wu, Taipei (TW); Chien-Hua Cheng, Taipei (TW); Wei-Tien Chen, Taipei (TW); Samuel Fanchiang, Taipei (TW)

(21) Appl. No.: 15/193,859

(22) Filed: Jun. 27, 2016

(30) Foreign Application Priority Data
Jun. 29, 2015 (CN) 2015103684568

(51) Int. Cl. G06F 1/32; H02H 7/20; G06F 1/20; H05K 7/14

(52) U.S. Cl. CPC G06F 1/3296; H05K 7/1492; H02H 7/20; G06F 1/3206; G06F 1/206

(57) ABSTRACT

A power supply circuit comprises a power supply unit for powering components of the computing server, a power regulator connected to the power supply unit for regulating electric power supply to the components, and an activator connected to the power regulator for activating the power regulator. The power regulator is configured to initiate adjustment of an amount of electric power supplied from the power supply unit to the components after being activated by the activator.

### CROSS-REFERENCE TO RELATED APPLICATIONS

This application claims priority under 35 U.S.C. §119 to Chinese Patent Application No. 2015103684568 filed on Jun. 29, 2015, the entire text of which is specifically incorporated by reference herein.

### BACKGROUND

Field of the Invention

Embodiments of the present invention relate to one or more power supply circuits for computing servers and one or more methods of using, configuring, modifying, repairing and upgrading the one or more power supply circuits.

Background of the Related Art

Computing servers (also known as servers or computer servers) have become increasingly prevalent and critical for providing web services and modern network communication. During system maintenance and upgrade operations, a computing server often has to support hot plugging operations without being shut down. However, the hot plugging operations may cause system malfunction, damage to system components or even injury to service technicians if handled inappropriately. Overcurrent protection circuits for protecting the computing servers are known, but are not sufficient to provide comprehensive protection to the computing servers

### BRIEF SUMMARY

One embodiment of the present invention provides a power supply circuit for a computing server, comprising a power supply unit for supplying electrical power to components of the computing server, a power regulator connected to the power supply unit for controlling an amount of electrical power supplied from the power supply unit to the components, and an activator connected to the power regulator for activating the power regulator, wherein the power regulator is configured to reduce the amount of electrical power supplied from the power supply unit to the components in response to receiving an activation signal from the activator, and wherein the power regulator is configured to cause gradual throttling of operational states of the components until the operational states are reduced from a first level defined by a first mode of power supply to a second level defined by a second mode of power supply, wherein the first mode provides a greater amount of electric power than the second mode.

Another embodiment of the present invention provides a method for operating a power supply circuit of a computing server. The method comprises receiving an activation signal from an activator, and reducing an amount of electric power supplied from a power supply unit to a plurality of components of the computing server in response to receiving the activation signal, and gradually reducing the power consumption of the plurality of components through multiple stepwise reductions in the operational states of the components.

### BRIEF DESCRIPTION OF THE SEVERAL VIEWS OF THE DRAWINGS

In order that the advantages of the various embodiments will be readily understood, a more particular description of the various embodiments briefly described above will be provided by reference to specific exemplary embodiments that are illustrated in the accompanying drawings, which depict only exemplary embodiments and are not to be considered to be limiting in scope. The various embodiments are to be described and explained with additional specificity and detail through the use of the accompanying drawings.

FIG. 1 is a schematic diagram of a power supply circuit for a computing server.

FIG. 2 illustrates the computing server having a system cover and a casing.

FIG. 3 is a flowchart of a method of using the power supply circuit.

FIG. 4 is a chart illustrating operating states of several components of the computing server with the power supply circuit.

### DETAILED DESCRIPTION

One embodiment of the present invention provides a power supply circuit for a computing sever. The power supply circuit comprises a power supply unit (PSU) for powering components of the computing server. The power supply unit is alternatively known as a power supply, which can convert alternating current (AC) mains (e.g. 230 volts at 50 Hz, 120 volts at 60 Hz) to low-voltage regulated direct current (DC) power (e.g. 12 volts, 5 volts) for internal components of the computing server. The internal components include one or more Central Processing Units (CPU), volatile memory (e.g. Random-Access Memory), non-volatile memory (e.g. Solid-State Drive or hard disk drive), one or more Graphics Processor Units (GPU), adapters, cooling fans, and other components.

The power supply circuit further comprises a power regulator connected to the power supply unit for regulating electric power supply from the power supply unit to the components of the computing server. The power regulator is operable to regulate, monitor, limit or even shut off the electric power supply such that the components may perform at desired rates or states.

The power supply circuit additionally comprises an activator connected to the power regulator for activating the power regulator by use of an electronic signal. The power regulator is configured to initiate adjustment or change of an electric power supply from the power supply unit to the components after receiving one or more electronic signals from the activator. The activator may be in the form of hardware or software. For example, when implemented by software or firmware, the activator can be displayed as a button on a display screen or panel of the computing server such that the activator can release electronic signals, commands or instruction to the power supply circuit for altering electric power supply. Before opening the computing server, a service technician can push/press/touch the activator displayed as an onscreen button such that the power supply circuit changes performance of the components to another state, consuming less electric power. In another example, when implemented as a hardware component, the activator can be a temperature sensor inside the computing sever. If excessively high temperature (e.g. 62° C.) is detected, the power supply circuit immediately adjusts its power supply to relevant components of the computing server such that the relevant components are prevented from permanent damage. In other words, the activator can be independent, or incorporated as a part of larger software package or hardware device for manual, automatic or hybrid operation.

The power supply circuit can adjust performance of the components and power distribution to the components depending on the external situation or software programming (e.g. predetermined control logic). According to the present application, the components of the computing server are arranged into several groups. Each of these groups is configured to receive predetermined amount of power supply. For example, the CPU, its cache and volatile memory associated to the CPU receive about 480 watt in a default state, providing the maximum performance. However, if the activator is triggered, the power supply circuit can reduce electric power consumption of the CPU, its cache and volatile memory connected to the CPU such that these components can decrease their performance, with or without cooperation with an Operating System software of the computing server.

The power supply circuit has the flexibility to protect the computing sever, with or without compromising computing performance of the server. For example, in a data center having a problem with air-conditioning, the power supply circuit can lower system performance and power consumption of the computing server such that the computing server can maintain its operation with lower heat generation. Thus, the computing server is prevented from premature damage by a hazardous ambient air temperature, providing more reliable computing service.

The power supply circuit enables the components of the computing server to be responsive to the external environment and their own operating condition. If the activator detects vibration, overheat, moisture or physical intrusion, the power supply circuit can immediately adjust performance of the components by changing a level of electric power supply to the components such that the computing server can continue to operate, yet having necessary protection.

The power regulator can be configured to adjust the electric power supply of the power supply unit from a first mode of power supply to a second mode of power supply. The first mode provides higher electric power or wattage than the second mode. For example, the first mode may be called short-circuit protection mode whereby all components connected to the power supply unit receive maximum electric power input (e.g. voltage and/or current) for achieving their excellent computing performance. In contrast, the second mode can be termed as 240VA protection mode whereby some or all components linked to the power supply unit obtain minimum electric power input for providing their least computing performance, yet without being shut down. Other modes of power supply may be defined depending on specific user requirements. For example, the power supply circuit can support Turbo Boost whereby relevant CPUs may run above their base operating frequency via dynamic control of their CPU's clock rate. The Turbo Boost is commonly referred to as “dynamic overclocking”. The increased clock rate is supported by the power supply circuit, corresponding to relevant processors' power, current and thermal limits, as well as the number of cores currently in use and the maximum frequency of the active cores.

More specifically, the first mode can be configured to provide about 480 watts, and/or the second mode may be configured to provide about 240 watts. The provided wattages of these modes are sufficient for supporting existing architectures or products of computing servers. Different modes or wattages may be provided by the power supply circuit to suit further variations or requirements. For example, a CPU and GPU may receive their power supply from a common source, plug, rail or channel such that their relevant mode may need to provide 960 watts or higher. These modes provide layers of protection to hardware components of the computing server.

The power regulator may comprise a power monitor and limit controller for controlling the electric power supply from the power supply unit to the components. The power monitor and limit controller periodically or continuously checks actual electric power consumed by relevant components (e.g. CPU). Upper and lower limits are applied to these components for preventing them from failing (e.g. overheating). The power monitor and limit controller thus provides dynamic, sufficient and optimised electric power supply to these components such that electric power consumption of the computing server is reduced or optimised, while reducing power wastage or heat generation.

The power monitor and limit controller can further comprise an electronic switch for connecting the power supply unit to the components. The electric switch operates swiftly to dynamically regulate the electric power supply to the components (e.g. GPU). The electronic switch may be any of various types, such as an optical switch, vacuum tube, IGBT (Insulated-Gate Bipolar Transistor), Bipolar Junction Transistor or other suitable devices. For example, the electronic switch may include one or more MOSFETs or MOSFET modules that is serially connected between the power supply unit and the relevant electronic components (e.g. CPU, GPU, fans).

Preferably, the power monitor and limit controller is configured to operate in the short-circuit protection mode for powering the components at their peak performance. In another preferred situation, the power monitor and limit controller may be configured to operate in a 240VA protection mode for powering the components at their minimum performance. These two modes may be independent or overlap. For example, in a cool environment (e.g. about 21° C. ambient air temperature), some components of the computing server (e.g. CPU and GPU) can operate at their maximum speed, while other components (e.g. fans) can operate at their minimum speed. In other words, the power supply circuit can provide optimized, algorithm-defined or user-preferred modes for various components of the computing server. In a further alternative, the power monitor and limit controller may be configured to operate in a 240VA protection mode for shutting off the electric power supply from the power supply unit to the components when detecting electric shock or current surge.

The power supply unit may comprise a plurality of channels for distributing the electric power supply. The total incoming power supply is thus divided into several equal or different portions for powering components of the computing server. Components that require higher power supply or more power demanding are allocated with sufficient power. The word “channel” may be alternatively known as “rail”. For example, the power supply unit may provide a +3.3V rail, +5V rail, −5V rail, +5V SB (standby) rail, +12V rail, or other voltage or current defined rails. Multiple channels or rails offer flexibility in power diverse types of components in the computing server.

The plurality of channels can be configured to operate according to predetermined priority settings. Mission critical components may be assigned with a higher priority over other components. The assignment of priority may be programmed or hardware built-in, such that the priority settings can be updated, changed, removed or upgraded. Users or manufacturers can possibly make relevant changes via Operating Systems or in factories.

The plurality of channels may comprise a first channel for powering a CPU and memory connected to the CPU, which may have a first or highest priority. Additionally, the plurality of channels can comprise a second channel for powering a GPU and its adapter that have a second or medium priority. Furthermore, the plurality of channels may comprise a third channel for powering a cooling unit (fans, misc.), which have a third or low priority. Further priority levels or multiple hierarchies in power supply can be defined, implemented, modified, dynamically or automatically adjusted when necessary. Hence, the power supply circuit presents a reliable, robust and stable solution to supplying power to computing servers. Moreover, power distribution over one or more channels of the power supply circuit may be fixed, equally distributed, dynamically adjusted or automatically balanced to suit power consumption of relevant components coupled to the channel. For example, the power supply circuit may allocate more power to components of higher power demand or priority.

The power regulator can comprise a power administrator for controlling the power supply unit. The power administrator may be in the form of one or more semiconductor chips. For example, the power administrator comprises a system management firmware and a FPGA, which are two separate integrated circuits. One of the system management firmware and the FPGA may be reprogrammed by a service technician or manufacturer such that operating schemes of the power supply circuit can be reconfigured to meet particular requirements. For example, after replacing certain components of the computing server, the FPGA is configured by a customer, a user or a designer at a data center, after being manufactured.

In one embodiment, the activator comprises an electrical switch. The activator may be configured to activate the power regulator if sensing intrusion to the computing server. In fact, the activator can be integrated into an Operating System or diagnostic software as a particular instruction or command such that the power supply circuit can initiate another mode of power supply (e.g. 240VA protection mode) once activated by the activator. The activator can alternatively be in the form of a light switch on the casing such that the service technician can turn on the light before opening the system cover for servicing. When the light is turned on for viewing internal component of the computing server, the activator integrated with the light switch automatically causes the power supply unit to enter a predetermined mode of power supply (e.g. 240VA protection mode).

In another embodiment, the activator comprises an electrical switch installed on a cover (alternatively known as system cover) of the computing server. The activator may be configured to activate the power regulator if the cover is detected as being open. Therefore, the electrical switch on the cover may be automatically activated when the cover opens. Accordingly, the power supply circuit intelligently enters another mode of power supply if the cover is opened, without additional user actions. Of course, the electrical switch can incorporate or take the form of a sensor, mechanical apparatus or some combination thereof. For example, the activator or electrical switch may include a light sensor such that the activator is triggered into action when the light sensor becomes exposed to ambient light within the computing server. The activator or electrical alternatively may have a temperature sensor for monitoring a temperature inside the computing server. When the temperature sensor detects overheating (e.g. server temperature higher than 61° C.), the activator can automatically make the power supply circuit to enter a protection mode (e.g. 240VA protection mode). An alert message (e.g. SMS or WhatsApp) or alarm can be sent to a service technician(s), user(s) or an off-site controller center when necessary.

The present invention provides a computing server that comprises a power supply circuit. The power supply circuit comprises a power supply unit for powering components of the computing server, a power regulator connected to the power supply unit for regulating electric power supply to the components, and an activator connected to the power regulator for activating the power regulator. The power regulator is configured to initiate adjustment of electric power supply from the power supply unit to the components after being activated by the activator.

Yet another embodiment of the present invention provides a method for operating a power supply circuit of a computing server. The method comprises a first step of detecting an activation (e.g. receiving an activation signal) from an activator, and a second step of adjusting an electric power supply from a power supply unit for powering components of the computing server. Accordingly, the power supply circuit operates independently or automatically for regulating power distribution to components of the computing server, in response to sensing a possible abnormality or special circumstances. The power supply circuit thus becomes intelligent and responsive, and is able to transform a static/fixed power supply pattern into a dynamic process, making the computing server safer, more reliable and robust.

The step of adjusting the electric power supply from the power supply unit can comprise a step of reducing the electric power supply from the power supply unit. Although a step of increasing or boosting the electric power supply is necessary at times, the power supply circuit decreases the power supply to selected groups of components in the computing server to provide a protection mechanism when facing an irregularity. For example, the power supply circuit can reduce the electric power supply to a GPU if the computing server does not provide rapid manipulation and acceleration for the creation of images in a frame buffer intended for output to a display.

The step of reducing the electric power supply from the power supply unit may comprise a step of adjusting a power consumption state of the components of the computing server. Each selected component or groups of components of the computing server can be assigned or defined with one or more states of operation or corresponding power consumption. The adjustment may be dynamically balanced or situation dependent, such that the computing server is optimized in its performance, protection, reliability and power consumption.

The step of reducing the electric power supply from the power supply unit may comprise a step of assigning different power consumption states to the components of the computing server (e.g. giving higher priority or defining five states to the CPU). For example, with the power supply circuit, the computing server may operate with the CPU at state P₂, GPU at state Pm and the fans at a state of 30% rpm (e.g. 0.3×8,000 rpm=2,400 rpm). The step of assigning can be programmed into relevant semiconductor chips (e.g. the FPGA), or by an Operating System (software) of the computing server.

The method of operating a power supply circuit may additionally comprise a step of switching to a short-circuit protection mode if the computing server is not requiring servicing, and/or switching to a 240VA protection mode if the computing server is requiring service. These two modes make it possible for the power supply to achieve maximum or minimum performance (without powering off). The power supply circuit may automatically switch between modes.

The method may further comprise a step of resuming full power supply if not requiring service. Most often, the computing server provides computing service (e.g. website hosting) through its network connection. Peak performance of the computing server may be reinstated automatically after server maintenance, so that the service technician or user is relieved from manually adjusting modes or states of relevant power supply.

Exemplary, non-limiting embodiments of the present invention will now be described with references to the above-mentioned figures.

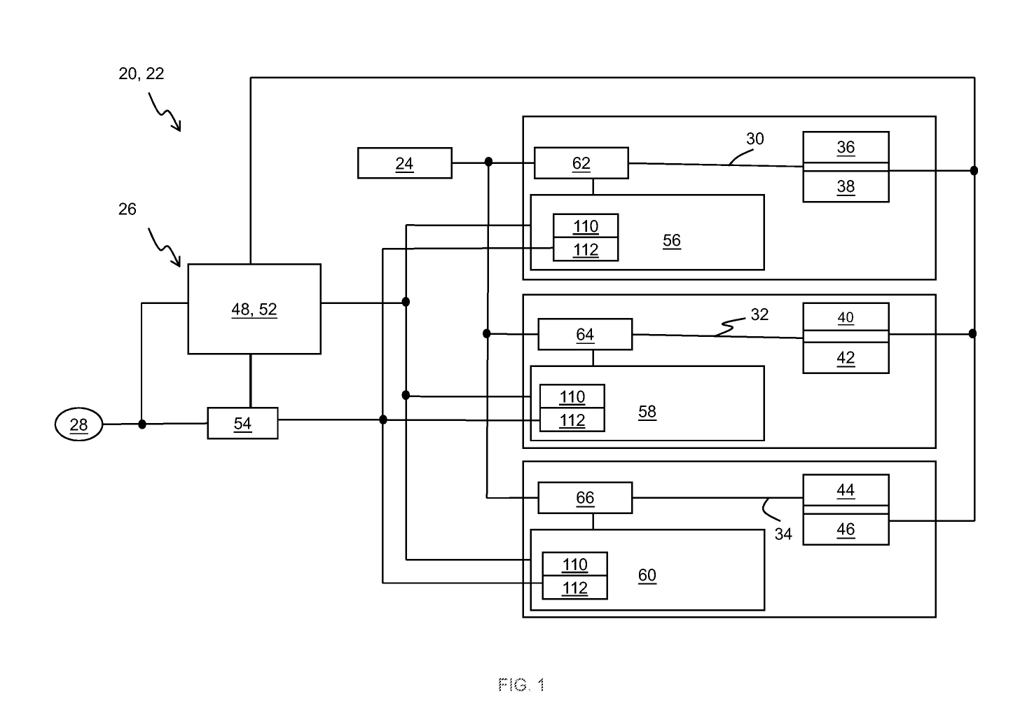

FIGS. 1 to 4 relate to an embodiment of the present application. In particular, FIG. 1 is a schematic diagram of a power distribution framework (i.e. circuitry) 20 for a computing server 22. The power distribution framework 20 has a power supply unit 24, a power regulator 26 and an activator 28. In FIG. 1, boxes represent various components, while lines signify electrical connections between the components, either by cables, wires, printed circuits and/or wireless connections (e.g. optical link). Text description is sometimes provided alongside the boxes or lines for providing terminologies or explaining functions of relevant entities. Particularly, joints of three or more electrical connections are indicated by dots.

The power supply unit 24 connects to a first channel (rail) 30, a second channel 32 and a third channel 34 for supplying electric power to various components of the computing server 22. According to FIG. 1, the first channel 30 is joined to a Central Processing Unit (CPU) 36 and its dual in-line memory modules (DIMM) 38 connected to the CPU 36 for processing, the second channel 32 is linked to a Graphics Processor Unit (GPU) 40 (also known as Visual Processor Unit or VPU) and its adapter 42. The third channel 34 is coupled to fans 44 and some miscellaneous components 46 (e.g. LED indicators) of the computing server 22. Each of the three channels 30, 32, 34 is connected to power supply unit 24 independently such that they receive about 480 Watts (480 VA) during stable operation respectively. Moreover, these three channels 30, 32, 34 are assigned with priorities by the power supply unit 24 such that the first channel 30 has higher priority over the second channel, and the second channel has higher priority over the third channel. In other words, in case of power shortage, the first channel 30 is given the preference in receiving electric power over other channels 32, 34, while the second channel 32 has been granted with preference in receiving electric power over the third channel 34.

The power regulator 26 has a power management host 48 and a power controller (also known as power monitor and limit controller). Particularly, the power regulator 26 further comprises a system management firmware 52 (semiconductor chip or integrated circuit comprised in the power management host 48) and a FPGA (Field-Programmable Gate Array) 54 that are connected to each other. The power management host 48 is further connected to the CPU 36 and the DIMM 38 directly. Similarly, the GPU 40 and its adapter 42 are both connected to the power management host 48. The power management host 48 is additionally joined to the fans 44 and the other components 46.

The power controller includes a first power controller 56, a second power controller 58 and a third power controller 60. Each of the power controllers 56, 58, 60 is connected to the power management host 48 via PMbus (Power Management Bus). These power controllers 56, 58, 60 additionally have electronic switches 62, 64, 66 that are connected between the power supply unit 24 and components 36, 38, 40, 42, 44, 46 of the computing server 22. Since these electronic switches 62, 64, 66 adopt MOSFETs (Metal-Oxide-Semiconductor Field-Effect Transistors, also known as MOS-FETs, or MOS FETs) as their critical components for operations, they are alternatively known as MOSFETs 62, 64, 66 for convenience. Each of these MOSFETs 62, 64, 66 is connected to their respective power controllers 56, 58, 60 individually. According to FIG. 1, the first MOSFET 62 is further connected between the power supply unit 24 and the CPU 36, as well as its associated volatile memory 38. The second MOSFET 62 is additionally linked between the power supply unit 24 and the GPU 40 (e.g. Intel's Xeon Phi accelerator), together with its adapter 42. The third MOSFET 66 is joined to both the fans 44 and the other components 46 of the computing server 22.

The power management host 48 provides electrical connection between the activator 28 and various components 36, 38, 40, 42, 44, 46 of the computing server 22. Particularly, the activator 28 is coupled to both the CPU 36 and its memory 38 via the power management host 48. The activator 28 is also coupled to the GPU 40 and the adapter 42 via the power management host 48. In parallel, the activator 28 is additionally coupled to the fans 44 and the other components via the power management host 48. The FPGA 54 has three parallel connections to the first power controller 56, the second power controller 58 and the third power controller 60. The FPGA 54 is connected to both the activator 28 and the power management host 48.

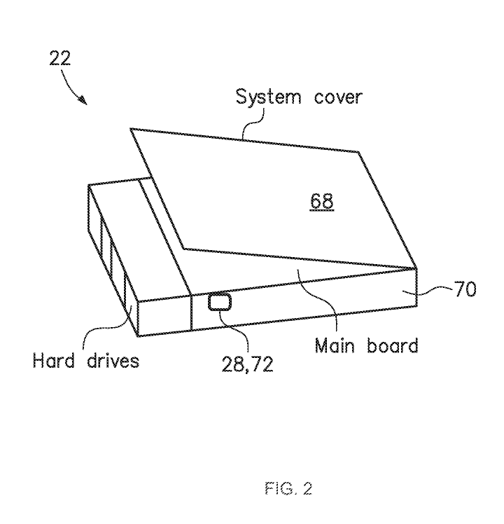

FIG. 2 illustrates the computing server 22 having a system cover 68 and a casing 70. The system cover 68 cooperates with the casing 70 such that most components of the computing server 22 are enclosed and protected by an enclosure formed by the system cover 68 and the casing 70. The system cover 68 is only required to be opened if technicians desire to inspect or access components of the computing server 22, such as for system repair or upgrading.

The activator 28 comprises the system cover 68 and a tactile switch 72 on the casing 70. The system cover 68 is closely attached to the casing 70 during normal/stable/usual computing operation. Since a button (not shown) of the tactile switch 72 is being pushed against the system cover 68, the tactile switch 72 has an open circuit, known as deactivated or not being activated. According to FIG. 1, the activator 28 is connected to both the power management host 48 and the FPGA 54. If the system cover 68 is opened, the button is relieved and the tactile switch 72 closes its circuit such that the activator 28 is activated for triggering operation of the power management host 48 and the FPGA 54.

Referred again to FIG. 1, the activator 28 is configured to provide one or more electrical signals to the power distribution framework 20 when activated. The activator 28 is directly connected to both the power management host 48 and the FPGA 54. Particularly, the FPGA 54 is a semiconductor chip or integrated circuit for configuring or programming after its manufacturing. FPGA configuration is generally specified using a hardware description language (HDL), similar to that used for an application-specific integrated circuit (ASIC). FPGAs (i.e. multiple pieces of FPGA) contain an array of programmable logic blocks, and a hierarchy of reconfigurable interconnects that allow the blocks to be “wired together”, like many logic gates that can be inter-wired in different configurations. Logic blocks can be configured to perform complex combinational functions, or merely simple logic gates like AND and XOR. In most FPGAs, logic blocks also include memory elements, which may be simple flip-flops or more complete blocks of memory.

The power supply unit 24 (PSU) is configured to convert mains AC (not shown) to low-voltage regulated DC power to be provided to the internal components 36, 38, 40, 42, 44, 46 of the computing server 22. Some power supplies have a manual selector for input voltage, while others automatically adapt to the supply voltage. The channels 30, 32, 34 may provide 12 V DC power respectively. In practice, these channels 30, 32, 34 are also known as rails.

Although the power management host 48 and the FPGA 54 are two separate semiconductor chips, they can be incorporated into a singular integrated circuit instead. Instead of implementing the MOSFETs 62, 64, 66, the power distributed framework can alternatively be replaced by other types of electronic switches, such as relays, vacuum tubes or other solid state devices (e.g. transistors). The fans 44 are alternatively known as cooling fans 44. In computing servers with liquid cooling facilities, these fans 44 may be replaced by pumps, fins and other heat dissipation constituents. The power controllers 56, 58, 60 are otherwise termed as power monitor and limit controllers.

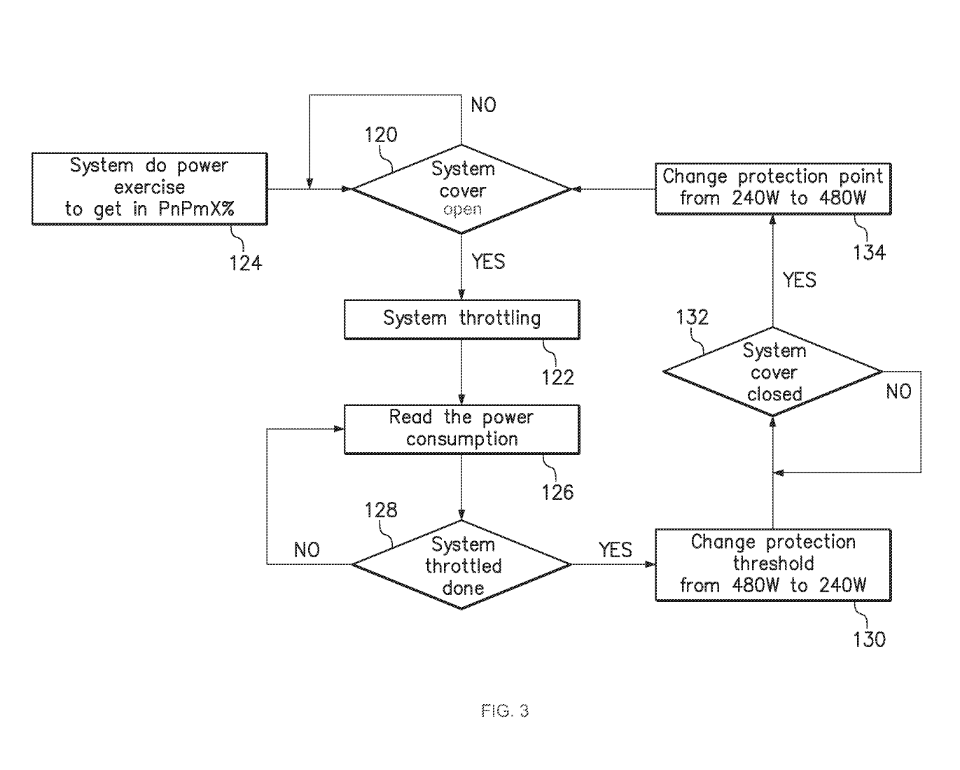

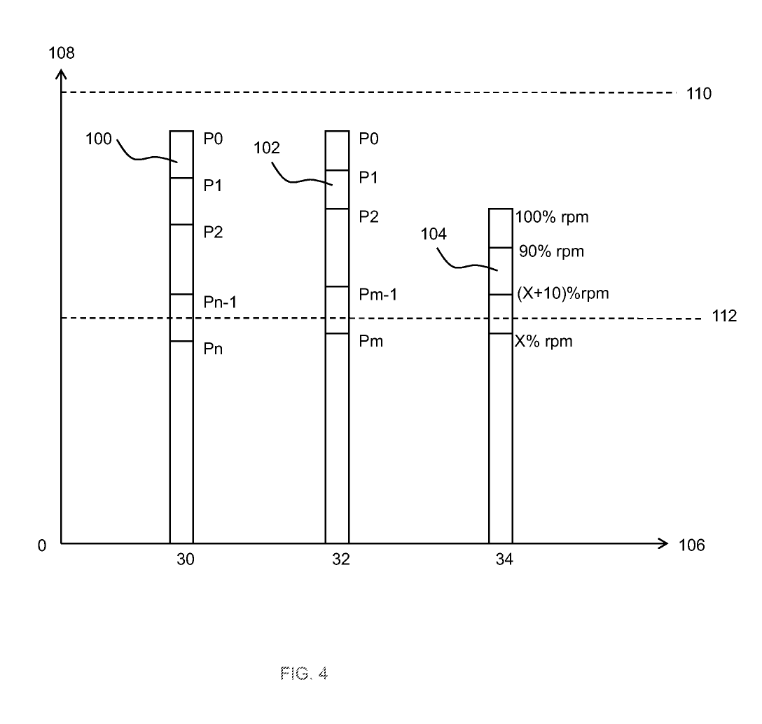

FIG. 3 is a flowchart of a method of using the power distribution framework. FIG. 4 illustrates operating states 100, 102, 104 of the several components 36, 38, 40, 42, 44, 46 of the computing server 22, which are associated with use of the power distribution framework.

During routine operation, the power distributed framework constantly examines whether the activator 28 has been triggered by opening of the system cover 68. If not, then the components 36, 38, 40, 42, 44, 46 of the computing server 22 perform power exercises (i.e. computing of power distribution according to embedded algorithms) to obtain predetermined operating states during system power on. The FPGA will use several commands to throttle channel 1, 2 and 3 step by step separately to get the desired protection threshold.

Referring to FIG. 4, the CPU 36 and its DIMM 38 (see FIG. 1) on the first channel 30 have a default state P₀ whereby the CPU 36 operates at its maximum speed for providing the best performance. The CPU 36 and its DIMM 38 also have several other states, known as P₁, P₂, . . . Pₙ₋₁, Pₙ whereby performance of the CPU 36 and its DIMM 38 decreases gradually with their corresponding reduction of electrical power consumption. Similarly, the GPU 40 and its adapter 42 (see FIG. 1) on the second channel 32 have a default state P₀ whereby the GPU 40 works at its highest clock rate for operating at its fastest speed. The GPU 40 and its adapter 42 have a number of operational states, known as P₁, P₂, . . . Pₙ₋₁, Pₙ, whereby the GPU 36 and its adapter 42 reduce their performance progressively with their corresponding diminishing electrical power consumption. Here, both “m” and “n” denote natural numbers (sometimes called the whole numbers) respectively, labelling discrete operating states P₀, P₁, P₂, . . . Pₙ₋₁, Pₙ. Since cooling capacity of the fans 44 are typically determined by their rotational speed in terms of rotations-per-minute (RPM or rpm), these fans 44 also have reduced cooling performance states, marked as 100% rpm, 90% rpm, . . . (x+10)% rpm and x % rpm, in which x refers to the desired rpm under protection threshold.

FIG. 4 is a chart illustrating how electric power is distributed to these different channels 30, 32, 34. States and electric power consumption of the various components 36, 38, 40, 42, 44, 46 are represented by a horizontal axis 106, and a vertical axis 108 for signifying rate of power consumption in wattage. Particularly, since each of the channels 30, 32, 34 has been limited to receive the maximum electric power of 480 Watt (W) and the minimum power of 240 Watt (i.e. 240 W), these upper and lower limits are indicated by two horizontal dash lines 110, 112 respectively. The upper horizontal line 110 represents the short-circuit protection mode 110, while the lower horizontal line 112 represents the 240VA protection mode 112.

According to FIG. 4, a first vertical column 100 displays CPU power states 100, including P₀, P₁, P₂, . . . , Pₙ₋₁, Pₙ, from the highest P₀ to the lowest state Pₙ. A second column 102 exhibits GPU power states 102, including P₀, P₁, P₂, . . . , Pₙ₋₁, Pₙ, from the highest P₀ to the lowest state Pₙ. Labels of power states for the GPU (e.g. Pₘ) denotes different electric power states than the power states of the CPU (e.g. Pₙ). Similarly, a third vertical column 104 shows fans' power states 104, including 100% rpm (e.g. 3,500 rpm), 90% rpm, (x+10)% rpm and x % rpm from the highest 100% rpm to the lowest state x % rpm (e.g. 600 rpm). Particularly, the highest states (i.e. P₀ of the CPU, P₀ of the GPU and 100% rpm of the fans) of these components 36, 38, 40, 42, 44, 46, are below the upper limit (i.e. 480 Watts) to each of these channels 30, 32, 34, while the lowest states (i.e. Pₙ of the CPU, Pₘ of the GPU and x % rpm of the fans) of these components 36, 38, 40, 42, 44, 46, are further below the lower limit (i.e. 240 Watts) to each of these channels 30, 32, 34.

In use, the computing server 22 typically operates at its peak performance whereby the CPU 36 and its volatile memory 38 consume approximately 450 Watts. Similarly, the GPU 40 and its adapter 42 receive about 440 Watts for providing excellent graphic processing. The fans 44 and other components 46 obtain about 360 Watts, whereby fans 44 spin at their maximum speeds. The system cover 68 is closely attached to the casing 70 such that the tactile switch 72 has a close circuit, enabling the short-circuit protection mode 110 of the computing server 22.

Referring back to FIG. 3, the system cover 68 (FIG. 2) may be opened (step 120) by a service technician such that the computing server 22 may undergo inspection by the service technician. A button (not shown) of the tactile switch 72 (FIG. 2) may be released and close its circuit such that both the FPGA 54 and the system management firmware 52 receive signals for triggering predetermined operations. Here, the cover opening is alternatively known as cover intrusion.

Continuing with FIG. 3, the predetermined operations may comprise system throttling (step 122), which is organized by the power regulator 26. The power regulator 26 is alternatively known as a throttling controller 26 because the both the system management firmware 52 and the FPGA 54 have embedded applications to balance the outbound publishing rates of the components 36, 38, 40, 42, 44, 46 with their inbound consumption rates. The throttling operation (step 122) optimizes available system resources for the processing profile, and prevents eventually unsustainable power consumption. For example, in an enterprise application integration (EAI) architecture, the throttling process (step 122) may be built into the enterprise application integration (EAI) architecture logic to prevent an expectedly slow end-system from becoming overloaded as a result of overly aggressive publishing from a middleware tier.

During system power on, the computing server 22 performs (step 124) the power exercise such that appropriate operational states (e.g. Pₙ, Pₘ, x % rpm) of the various components 36, 38, 40, 42, 44, 46 are determined, arrived and maintained, depending how sufficient their incoming power is available from the power supply unit 24.

Following the throttling process (step 122), both the system management firmware 52 and the FPGA 54 continuously read (step 126) power consumption rates of these components 36, 38, 40, 42, 44, 46 till completing (step 128) of the throttling process by the power administrator 48. This means that the power consumption rates of the components 31, 38, 40, 42, 44, 46 have arrived at the appropriate operational states (e.g. Pₙ, Pₘ, x % rpm), as predetermined during system power exercise (at step 124). When the system cover 68 is open, the power controllers 56, 58, 60 shift (step 130) protection threshold from the previous upper limit 110 of 480 W to the lower limit 112 of 240 W. The components 36, 38, 40, 42, 44, 46 thus operate below the lower limit 112 at their respective minimum operating states Pₙ for CPU 36 and its DIMM 38, Pₘ for GPU 40 and its adapter 42, and x % rpm for fans 44. These minimum operating states Pₙ, Pₘ, and x % are maintained as long as the system cover 68 is still open or removed. The supply of power from various channels 30, 32, 34 to these components 36, 38, 40, 42, 44, 46 is regulated by the MOSFETs 62, 64, 66. In particular, the throttling of each of the components 36, 38, 40, 42, 44, 46 means that the power consumption of these components is reduced from a present operational state (e.g. P₁, P₂, x+50% rpm) to a next lower operational states (i.e. Pₙ₋₁, Pₘ₋₁, x+40% rpm). However, it should be appreciated that the throttling may also lower the power consumption of the components of the computer server to a second, or even third, lower operational state (e.g. Pₙ₋₂, Pₘ₋₂, x+30% rpm).

After the inspection, the service technician flips the system cover 68 to close the casing 70 such that the button of the tactile switch 72 is pushed down by the system cover 68. Electrical connections within the tactile switch 72 are separated again such that the tactile switch 72 is short-circuited. Electronic signal of this short-circuit is interpreted by the power distributed framework as system cover closing (step 132), close or closure. Upon detecting a short-circuit, with further delay of less than 1 second, the power regulator 26 changes (step 134) the protection mode from the previous 240 W 112 to the original 480 W 110. Accordingly, the power supply circuit 20 calculates appropriate power consumption rates such that these components 36, 38, 40, 42, 44, 46 receive their maximum power supply, under the short-circuit protection mode 110.

It will be apparent that various other modifications and adaptations of the application will be apparent to the person skilled in the art after reading the foregoing disclosure without departing from the spirit and scope of the application and it is intended that all such modifications and adaptations come within the scope of the appended claims.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable storage medium(s) may be utilized. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device. Furthermore, any program instruction or code that is embodied on such computer readable storage medium (including forms referred to as volatile memory) is, for the avoidance of doubt, considered “non-transitory”.

Program code embodied on a computer readable storage medium may be transmitted using any appropriate medium, including but not limited to wireless, wireline, optical fiber cable, RF, etc., or any suitable combination of the foregoing. Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention may be described with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, and/or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored as non-transitory program instructions in a computer readable storage medium that can direct a computer, other programmable data processing apparatus, or other devices to function in a particular manner, such that the program instructions stored in the computer readable storage medium produce an article of manufacture including non-transitory program instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A power supply circuit for a computing server, comprising:
a power supply unit for supplying electrical power to components of the computing server;
a power regulator connected to the power supply unit for controlling an amount of electrical power supplied from the power supply unit to the components; and
an activator connected to the power regulator for activating the power regulator, wherein the power regulator is configured to reduce the amount of electrical power supplied from the power supply unit to the components in response to receiving an activation signal from the activator, and wherein the power regulator is configured to cause gradual throttling of operational states of the components until the operational states are reduced from a first level defined by a first mode of power supply to a second level defined by a second mode of power supply, wherein the first mode provides a greater amount of electric power than the second mode.

2. The power supply circuit of claim 1, wherein the first mode causes the power supply to provide about 480 Watts, and the second mode causes the power supply to provide about 240 Watts.

3. The power supply circuit of claim 1, wherein the power regulator comprises a power monitor and limit controller for controlling the amount of electric power supplied from the power supply unit to the components.

4. The power supply circuit of claim 3, wherein the power monitor and limit controller includes an electronic switch for controllably connecting and disconnecting the power supply unit and the components.

5. The power supply circuit of claim 4, wherein the power monitor and limit controller is configured to operate in a short-circuit protection mode for operating the components at their peak performance.

6. The power supply circuit of claim 4, wherein the power monitor and limit controller is configured to operate in a 240VA protection mode for operating the components at their minimum performance.

7. The power supply circuit of claim 1, wherein the power supply unit comprises a plurality of channels for distributing the electric power to the components.

8. The power supply circuit of claim 7, wherein each of the channels includes a switch for shutting off power to the components connected to the channel.

9. The power supply circuit of claim 7, wherein each of the plurality of channels are configured to operate according to predetermined priority settings.

10. The power supply circuit of claim 7, wherein the plurality of channels include a first channel for powering a CPU and its memory, a second channel for powering a GPU and its adapter, and a third channel for powering a cooling unit.

11. The power supply circuit of claim 1, wherein the power regulator comprises a power administrator for controlling the power supply unit.

12. The power supply circuit of claim 1, wherein the activator includes an electrical switch, and wherein the activator is configured to activate the power regulator in response to sensing activation of the electrical switch.

13. The power supply circuit of claim 12, wherein the electrical switch is positioned to send an activation signal to the power regulator in response to opening of a cover to a casing that houses the computing server components.

14. A method for operating a power supply circuit of a computing server, the method comprising:
receiving an activation signal from an activator; and
reducing an amount of electric power supplied from a power supply unit to a plurality of components of the computing server in response to receiving the activation signal; and
gradually reducing the power consumption of the plurality of components through multiple stepwise reductions in the operational states of the components.

15. The method of claim 14, wherein reducing an amount of electric power supplied from a power supply unit to the plurality of components of the computing server, includes causing the power supply unit to operate in a short-circuit protection mode prior to detecting the activation signal, and causing the power supply unit to operate in a 240VA protection mode in response to receiving the activation signal.

16. The method of claim 14, wherein the activator includes an electrical switch, and wherein the activator is configured to activate the power regulator in response to receiving the activation signal from the electrical switch.

17. The method of claim 16, wherein the electrical switch is positioned to send an activation signal to the power regulator in response to opening of a cover to a casing that houses the computing server components.
